(19) United States
(12) Patent Application Publication
(10) Pub. No.: US 2024/0177918 A1
(43) Pub. Date: May 30, 2024

(54) GLASS EMBEDDED TRUE AIR CORE INDUCTORS

(71) Applicant: Intel Corporation, Santa Clara, CA (US)

(72) Inventors: Suddhasattwa NAD, Chandler, AZ (US); Brandon C. MARIN, Gilbert, AZ (US); Jeremy D. ECTON, Gilbert, AZ (US); Srinivas V. PIETAMBARAM, Chandler, AZ (US); Gang DUAN, Chandler, AZ (US); Mohammad Mamunur RAHMAN, Gilbert, AZ (US)

(21) Appl. No.: 18/071,237

(22) Filed: Nov. 29, 2022

(51) Int. Cl. H01F 27/28; H01F 27/30; H01F 41/04; H01L 23/08; H01L 23/31

(52) U.S. Cl. CPC H01F 27/2804; H01F 27/306; H01F 41/041; H01L 23/08; H01L 23/3128; H01F 2027/2809; H01F 2027/2819

(57) ABSTRACT

Embodiments disclosed herein include a package core. In an embodiment, the package core comprises a core substrate, a first opening through the core substrate, a second opening through the core substrate and adjacent to the first opening, and a first structure around the core substrate between the first opening and the second opening. In an embodiment, the first structure is electrically conductive. The package core may further comprise a second structure around the core substrate outside of the first opening and the second opening, where the second structure is electrically conductive.

### TECHNICAL FIELD

Embodiments of the present disclosure relate to electronic packages, and more particularly to package substrates with glass cores that include a true air core inductor.

### BACKGROUND

Power regulation for semiconductor architectures often include voltage regulators (VRs). In some instances, the inductors for the VRs are provided in the package substrate. One type of inductor includes a so called air core inductor. While referred to as having an “air core”, existing solutions include a dielectric core. That is, dielectric buildup materials fill the core of the inductor. In other instances, coaxial inductor architectures are provided through the core. In a coaxial architecture conductive vias pass through the core of the package substrate and a magnetic core fills the space between the conductive vias. Coaxial architectures provide good inductance performance, but are limited in that they are a high cost solution.

### BRIEF DESCRIPTION OF THE DRAWINGS

FIG. 1 is a cross-sectional illustration of a portion of a package substrate that includes air core inductors through a core, in accordance with an embodiment.

FIG. 2 is a cross-sectional illustration of a portion of a package substrate that includes air core inductors with tapered sidewalls through a core, in accordance with an embodiment.

FIG. 3A is a cross-sectional illustration of a glass core, in accordance with an embodiment.

FIG. 3B is a cross-sectional illustration of the glass core with a plurality of first via openings, in accordance with an embodiment.

FIG. 3C is a cross-sectional illustration of the glass core with a seed layer disposed over surfaces of the glass core, in accordance with an embodiment.

FIG. 3D is a cross-sectional illustration of the glass core with a resist layer disposed over portions of the seed layer, in accordance with an embodiment.

FIG. 3E is a cross-sectional illustration of the glass core after conductive structures are plated up from the seed layer, in accordance with an embodiment.

FIG. 3F is a cross-sectional illustration of the glass core after the resist layer is removed, in accordance with an embodiment.

FIG. 3G is a cross-sectional illustration of the glass core after the exposed portions of the seed layer are removed, in accordance with an embodiment.

FIG. 3H is a cross-sectional illustration of the glass core after exposed portions of the glass core are removed to provide an air core inductor, in accordance with an embodiment.

FIG. 4A is a cross-sectional illustration of a glass core, in accordance with an embodiment.

FIG. 4B is a cross-sectional illustration of the glass core after a plurality of first via openings with tapered sidewalls are formed through the glass core, in accordance with an embodiment.

FIG. 4C is a cross-sectional illustration of the glass core after a seed layer is disposed over the surfaces of the glass core, in accordance with an embodiment.

FIG. 4D is a cross-sectional illustration of the glass core after a mask layer is provided over portions of the seed layer, in accordance with an embodiment.

FIG. 4E is a cross-sectional illustration of the glass core after a conductive layer is plated over the seed layer, in accordance with an embodiment.

FIG. 4F is a cross-sectional illustration of the glass core after the mask layer is removed, in accordance with an embodiment.

FIG. 4G is a cross-sectional illustration of the glass core after exposed portions of the seed layer are removed, in accordance with an embodiment.

FIG. 4H is a cross-sectional illustration of the glass core after exposed portions of the glass core are removed to provide an air core inductor, in accordance with an embodiment.

FIG. 5 is a cross-sectional illustration of an electronic system with an air core inductor, in accordance with an embodiment.

FIG. 6 is a schematic of a computing device built in accordance with an embodiment.

### EMBODIMENTS OF THE PRESENT DISCLOSURE

Described herein are package substrates with glass cores that include a true air core inductor, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, inductor architectures are necessary for advanced voltage regulator (VR) solutions. In some embodiments, the VR solutions may be referred to as fully integrated VR (FIVR) architectures. Previously, air core inductors in the package substrate or coaxial inductor architectures have been used in order to provide the necessary inductance. However, existing air core inductors do not truly have an air core. Instead, the buildup film fills the gap between the inductive loop. In the case of coaxial architectures, the cost of such solutions is limiting.

Accordingly, embodiments disclosed herein include true air gap inductor architectures. The air gap is provided within the core of the package substrate. That is, conductive features may be plated into via openings in the core. After plating the conductive features, portions of the core are removed in order to provide the air core architecture. In an embodiment, the core may be a glass core. The vias through the core may have substantially vertical sidewalls. In other embodiments, the vias may have a tapered or hourglass shaped cross-section. As used herein, an “hourglass shaped” cross-section includes a shape with a middle that is narrower than the ends.

In an embodiment, the glass core may be patterned with any suitable patterning process. For example, a laser ablation process may be used in some embodiments. In the case of thin glass cores, the sidewalls may be vertical. In the case of thicker glass cores, the sidewalls may be tapered or have an hourglass shaped profile. In an alternative embodiment, a laser assisted patterning process may be used to pattern the glass core. In such an embodiment, a laser exposure of the glass core changes the microstructure or phase of the glass. A subsequent etching process (e.g., a wet etching process) preferentially removes the exposed regions of the glass core.

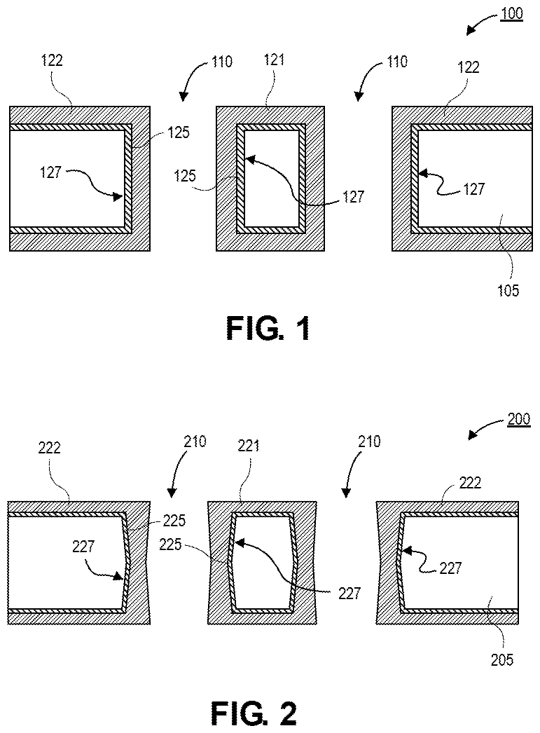

Referring now to FIG. 1, a cross-sectional illustration of a portion of a package substrate 100 is shown, in accordance with an embodiment. In an embodiment, the core 105 of the package substrate 100 is shown. It is to be appreciated that buildup layers above and below the core 105 may be provided, as will be described in greater detail below. In an embodiment, the core 105 may comprise glass. Particularly, the core 105 may comprise substantially all glass. That is, the core 105 is a different material than traditional dielectric cores that include a dielectric material with glass fiber reinforcement. In an embodiment, the glass core 105 may comprise a borosilicate glass, a fused silica glass, or any other type of glass. In some embodiments, the core 105 may be compatible with laser assisted patterning processes, such as those described in greater detail above.

In an embodiment, the core 105 may comprise openings 110. The openings 110 may be air gaps. That is, in some embodiments, the openings 110 are not filled with any solid material, and substantially only air fills the openings 110. In an embodiment, a first conductive structure 121 may be provided between the openings 110. A second conductive structure 122 may be provided outside of the openings 110. In the illustrated embodiment, the two openings 110 are shown as different structures. However, in some embodiments, the opening 110 on the left is connected to the opening 110 on the right outside of the plane of FIG. 1. Additionally, while the portion of the core 105 between the openings 110 is shown as floating, it is to be appreciated that the floating portion of the core 105 may be connected to other portions of the core 105 outside of the plane of FIG. 1. In an embodiment, the openings 110 may have an aspect ratio (height:width) that is approximately 5:1 or greater, or approximately 10:1 or greater.

In an embodiment, the first conductive structure 121 may wrap around portions of the core 105. That is, inner sidewalls of the openings 110 and the top and bottom surface of the core 105 may be plated by the conductive material of the first conductive structure 121. Similarly, the second conductive structure 122 may be plated above and below the core 105 and along outer sidewalls of the openings 110. In some embodiments, the first conductive structure 121 and the second conductive structure 122 may be plated up from a seed layer 125. The seed layer 125 may comprise copper and/or platinum in some embodiments.

As shown, the sidewalls 127 of the openings 110 are substantially vertical in FIG. 1. The vertical sidewalls may be formed by a laser ablation patterning process through the glass core 105. In embodiments with cores 105 with smaller thicknesses, the laser ablation results in a substantially vertical sidewall 127 for the openings 110. In an embodiment, the thickness of the core 105 may be approximately 100 μm or lower in some embodiments. As used herein, “approximately” may refer to a range of values within ten percent of the stated value. For example, approximately 100 μm may refer to a range between 90 μm and 110 μm. Though, thicker cores 105 may also be used in some embodiments. Additionally, while described as being formed with a laser ablation process, it is to be appreciated that any patterning process may be used to form the openings 110, such as a mechanical drilling process, a laser assisted patterning process, or the like.

Referring now to FIG. 2, a cross-sectional illustration of a portion of a package substrate 200 is shown, in accordance with an embodiment. In an embodiment, the core 205 of the package substrate 200 is shown. It is to be appreciated that buildup layers above and below the core 205 may be provided, as will be described in greater detail below. In an embodiment, the core 205 may comprise glass. Particularly, the core 205 may comprise substantially all glass. In an embodiment, the glass core 205 may comprise a borosilicate glass, a fused silica glass, or any other type of glass. In some embodiments, the core 205 may be compatible with laser assisted patterning processes, such as those described in greater detail above.

In an embodiment, the core 205 may comprise openings 210. The openings 210 may be air gaps. That is, in some embodiments, the openings 210 are not filled with any solid material, and substantially only air fills the openings 210. In an embodiment, a first conductive structure 221 may be provided between the openings 210. A second conductive structure 222 may be provided outside of the openings 210. In the illustrated embodiment, the two openings 210 are shown as different structures. However, in some embodiments, the opening 210 on the left is connected to the opening 210 on the right outside of the plane of FIG. 2. Additionally, while the portion of the core 205 between the openings 210 is shown as floating, it is to be appreciated that the floating portion of the core 205 may be connected to other portions of the core 205 outside of the plane of FIG. 2. In an embodiment, the openings 210 may have an aspect ratio (height:width) that is approximately 5:1 or greater, or approximately 10:1 or greater.

In an embodiment, the first conductive structure 221 may wrap around portions of the core 205. That is, inner sidewalls of the openings 210 and the top and bottom surface of the core 205 may be plated by the conductive material of the first conductive structure 221. Similarly, the second conductive structure 222 may be plated above and below the core 205 and along outer sidewalls of the openings 210. In some embodiments, the first conductive structure 221 and the second conductive structure 222 may be plated up from a seed layer 225. The seed layer 225 may comprise copper and/or platinum in some embodiments.

As shown, the sidewalls 227 of the openings 210 are tapered in FIG. 2. More particularly, the sidewalls 227 have a dual tapered shape. For example, the openings 210 may be referred to as having an hourglass shaped profile. The tapered sidewalls 227 may be formed by a laser ablation patterning process through the glass core 205. In the case of a dual tapered structure, a laser ablation from both above and below the core 205 may be used. In an embodiment, tapered sidewalls 227 may be present in relatively thick glass cores 205. For example, glass cores 205 may include a thickness up to approximately 1,000 μm. Though, thicker cores 205 may also be used in some embodiments. While a dual tapered shape is shown in FIG. 2, it is to be appreciated that a single taper may be implemented when single sided patterning processes are used. In such an embodiment, a top of the opening 210 may be wider than a bottom of the opening 210.

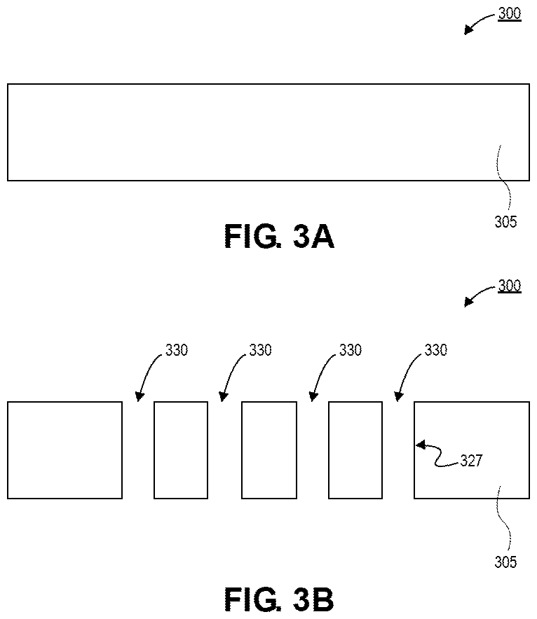

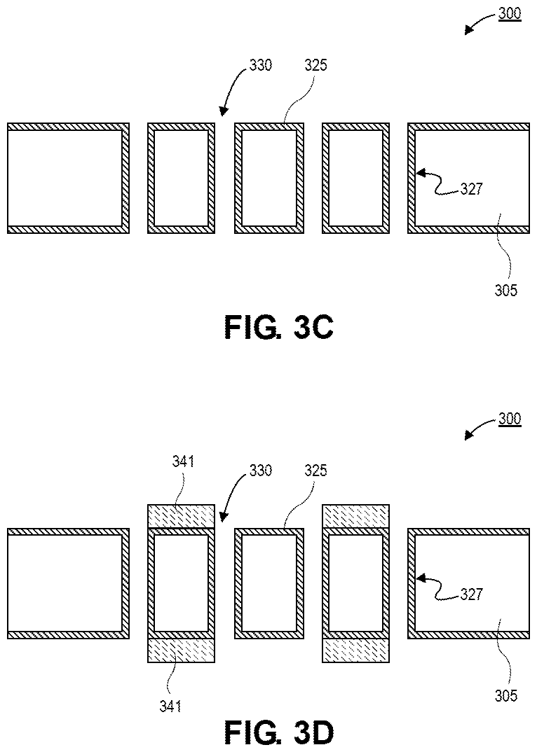

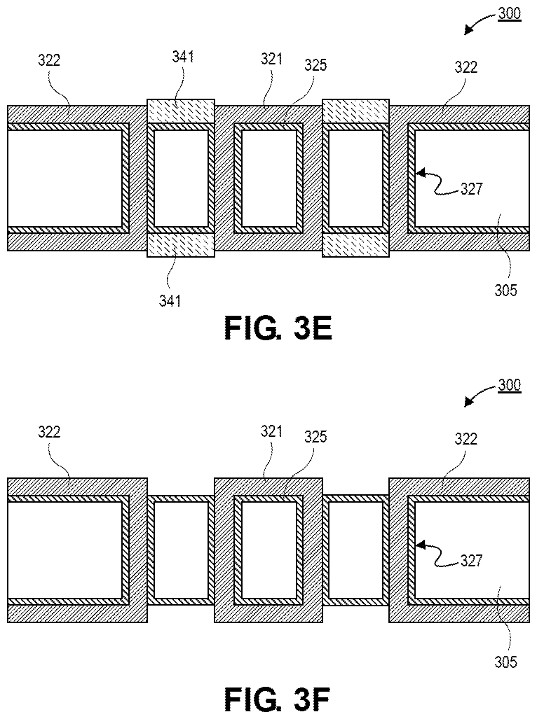

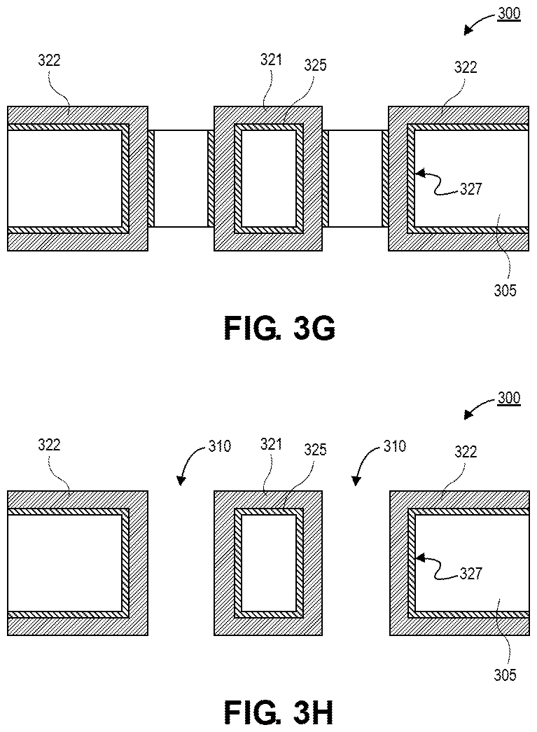

Referring now to FIGS. 3A-3H, a series of cross-sectional illustrations depicting a process for forming a portion of a package substrate 300 is shown, in accordance with an embodiment. In an embodiment, the package substrate 300 comprises a core 305 with openings to form air core inductors. In an embodiment, the core 305 may include openings with substantially vertical sidewalls.

Referring now to FIG. 3A, a cross-sectional illustration of a portion of a package substrate 300 at a stage of manufacture is shown, in accordance with an embodiment. In an embodiment, the package substrate 300 comprises a core 305. The core 305 may be a glass core 305. The glass core 305 may be a glass material suitable for laser assisted patterning processes, laser ablation processes, or the like. In an embodiment, the core 305 may have a thickness that is up to approximately 1,000 μm thick. Though, thicker cores 305 may also be used in some embodiments.

Referring now to FIG. 3B, a cross-sectional illustration of the package substrate 300 after a plurality of first holes 330 are provided through the core 305 is shown, in accordance with an embodiment. In an embodiment, the first holes 330 may be provided entirely through a thickness of the core 305. The first holes 330 may be formed with a laser ablation process, a laser assisted patterning process, or any other suitable patterning process. In an embodiment, the first holes 330 may have sidewalls 327 that are substantially vertical. While shown as being truly vertical, in some embodiments the sidewalls 327 may have a slight taper. For example, top widths of the first holes 330 may be slightly larger than bottom widths of the first holes 330. In the illustrated embodiment, the plurality of first holes 330 includes a set of four first holes 330. The four first holes 330 are used in order to provide an air core inductor with a first conductive structure surrounded by air gaps. For example, the leftmost floating portion of the core 305 and the rightmost floating portion of the core 305 may be removed in subsequent processing in order to form the air gaps. In an embodiment, the first holes 330 may have an aspect ratio (height:width) that is approximately 5:1 or greater, or approximately 10:1 or greater.

Referring now to FIG. 3C, a cross-sectional illustration of the package substrate 300 after a seed layer 325 is formed over exposed surfaces of the core 305 is shown, in accordance with an embodiment. In an embodiment, the seed layer 325 may be formed with a physical deposition process, such as sputtering, physical vapor deposition (PVD), or the like. In an embodiment, the seed layer 325 may comprise copper and/or platinum. In an embodiment, the seed layer 325 may be provided over the top surface of the core 305, the bottom surface of the core 305, and along sidewalls 327 of the first holes 330.

Referring now to FIG. 3D, a cross-sectional illustration of the package substrate 300 after a mask layer 341 is deposited on the core 305 is shown, in accordance with an embodiment. In an embodiment, the mask layer 341 may be a dry film resist (DFR) or the like. The mask layer 341 may be deposited over portions of the core 305 where metal layers are not desired. For example, the mask layer 341 is provided above and below the leftmost floating portion of the core 305 and the rightmost floating portion of the core 305. That is, a center floating portion of the core 305 and the remainder of the core 305 are left without an overlying/underlying mask layer 341.

Referring now to FIG. 3E, a cross-sectional illustration of the package substrate 300 after conductive structures 321 and 322 are plated is shown, in accordance with an embodiment. In an embodiment, first conductive structure 321 may be provided around the middle floating portion of the core 305. That is, a conductive layer may entirely surround the middle floating portion of the core 305. A second conductive structure 322 may be provided outside of the mask layers 341. The second conductive structure 322 may also comprise conductive material above and below the core 305, as well as over the sidewalls 327 of the core 305. In an embodiment, the first conductive structure 321 and the second conductive structure 322 may be formed with any suitable conductive material. For example, the first conductive structure 321 and the second conductive structure 322 may comprise copper or the like. The first conductive structure 321 and the second conductive structure 322 may be formed with a plating process, such as an electrolytic plating process, or the like.

Referring now to FIG. 3F, a cross-sectional illustration of the package substrate 300 after the mask layer 341 is removed is shown, in accordance with an embodiment. In an embodiment, the mask layer 341 may be removed with a resist stripping process, an etching process, or the like. Removal of the mask layer 341 results in the exposure of the seed layer 325 over the outer floating portions of the core 305. The exposed portions of the seed layer 325 are located at positions where the air gaps are desired.

Referring now to FIG. 3G, a cross-sectional illustration of the package substrate 300 after the exposed portions of the seed layer 325 are removed is shown, in accordance with an embodiment. In an embodiment, the exposed portions of the seed layer 325 may be removed with a flash etching process or the like. A flash etching process may refer to a rapid etch that is sufficient to remove the seed layer 325 without significantly reducing the thickness of the first conductive structure 321 and the second conductive structure 322. Removal of the seed layer 325 results in the exposure of portions of the underlying core 305.

Referring now to FIG. 3H, a cross-sectional illustration of the package substrate 300 after the floating portions of the core 305 are removed to form air gaps 310 is shown, in accordance with an embodiment. In an embodiment, the air gaps 310 may be formed by etching away the exposed portions of the core 305. For example, a wet etching process that is selective to the core 305 may be used to form the air gaps 310. In an embodiment, portions of the seed layer 325 along sidewalls of the air gaps 310 may also be removed. However, in some embodiments, portions of the seed layer 325 may persist on the sidewalls of the air gaps 310 in some embodiments. As shown, the air gaps 310 have substantially vertical sidewalls.

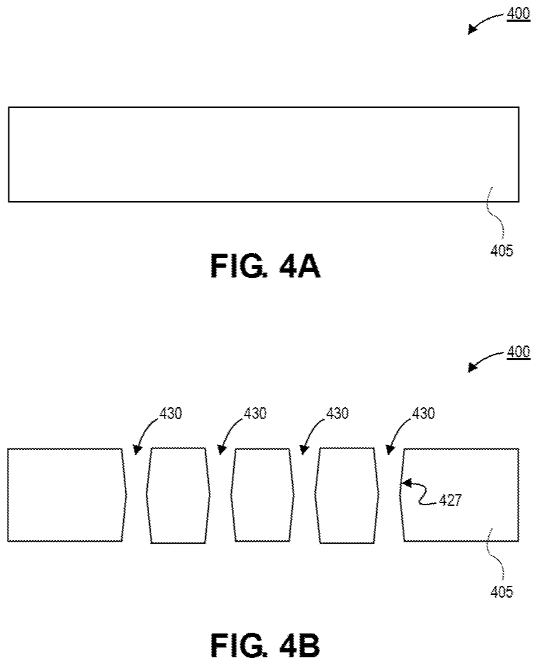

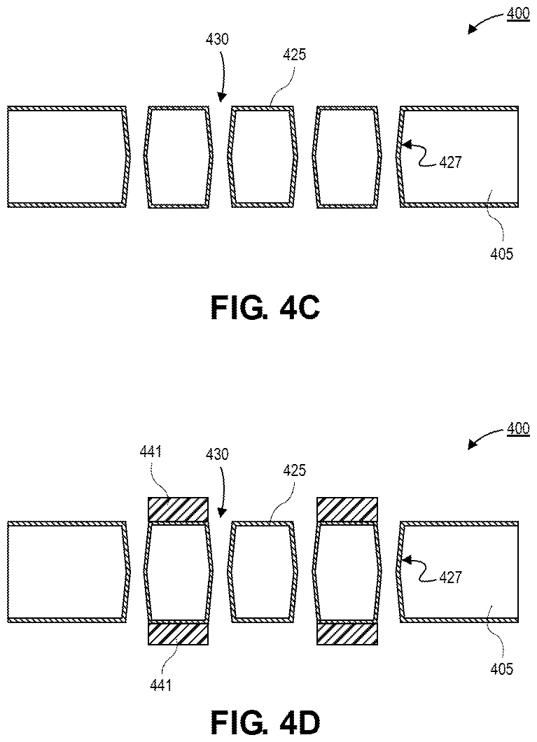

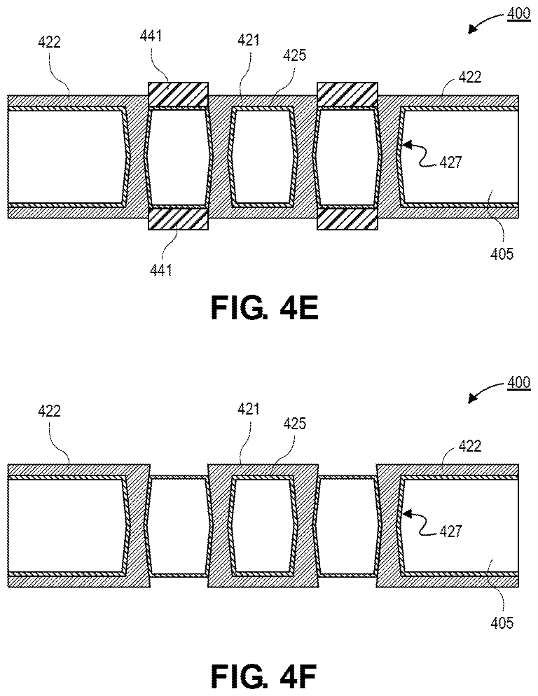

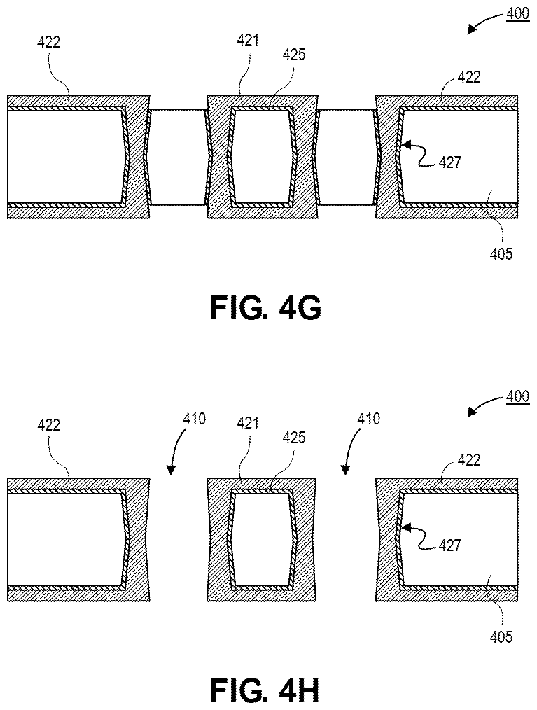

Referring now to FIGS. 4A-4H, a series of cross-sectional illustrations depicting a process for forming a portion of a package substrate 400 is shown, in accordance with an embodiment. In an embodiment, the package substrate 400 comprises a core 405 with openings to form air core inductors. In an embodiment, the core 405 may include openings with tapered sidewalls.

Referring now to FIG. 4A, a cross-sectional illustration of a portion of a package substrate 400 at a stage of manufacture is shown, in accordance with an embodiment. In an embodiment, the package substrate 400 comprises a core 405. The core 405 may be a glass core 405. The glass core 405 may be a glass material suitable for laser assisted patterning processes, laser ablation processes, or the like. In an embodiment, the core 405 may have a thickness that is up to approximately 1,000 μm thick. Though, thicker cores 405 may also be used in some embodiments.

Referring now to FIG. 4B, a cross-sectional illustration of the package substrate 400 after a plurality of first holes 430 are provided through the core 405 is shown, in accordance with an embodiment. In an embodiment, the first holes 430 may be provided entirely through a thickness of the core 405. The first holes 430 may be formed with a laser ablation process, a laser assisted patterning process, or any other suitable patterning process. In an embodiment, the first holes 430 may have sidewalls 427 that are tapered. In some embodiments, the first holes 430 may have a dual taper shape, such as an hourglass shaped profile. In the illustrated embodiment, the plurality of first holes 430 includes a set of four first holes 430. The four first holes 430 are used in order to provide an air core inductor with a first conductive structure surrounded by air gaps. For example, the leftmost floating portion of the core 405 and the rightmost floating portion of the core 405 may be removed in subsequent processing in order to form the air gaps. In an embodiment, the first holes 430 may have an aspect ratio (height:width) that is approximately 5:1 or greater, or approximately 10:1 or greater.

Referring now to FIG. 4C, a cross-sectional illustration of the package substrate 400 after a seed layer 425 is formed over exposed surfaces of the core 405 is shown, in accordance with an embodiment. In an embodiment, the seed layer 425 may be formed with a physical deposition process, such as sputtering, PVD, or the like. In an embodiment, the seed layer 425 may comprise copper and/or platinum. In an embodiment, the seed layer 425 may be provided over the top surface of the core 405, the bottom surface of the core 405, and along sidewalls 427 of the first holes 430.

Referring now to FIG. 4D, a cross-sectional illustration of the package substrate 400 after a mask layer 441 is deposited on the core 405 is shown, in accordance with an embodiment. In an embodiment, the mask layer 441 may be a DFR or the like. The mask layer 441 may be deposited over portions of the core 405 where metal layers are not desired. For example, the mask layer 441 is provided above and below the leftmost floating portion of the core 405 and the rightmost floating portion of the core 405. That is, a center floating portion of the core 405 and the remainder of the core 405 are left without an overlying/underlying mask layer 441.

Referring now to FIG. 4E, a cross-sectional illustration of the package substrate 400 after conductive structures 421 and 422 are plated is shown, in accordance with an embodiment. In an embodiment, first conductive structure 421 may be provided around the middle floating portion of the core 405. That is, a conductive layer may entirely surround the middle floating portion of the core 405. A second conductive structure 422 may be provided outside of the mask layers 441. The second conductive structure 422 may also comprise conductive material above and below the core 405, as well as over the sidewalls 427 of the core 405. In an embodiment, the first conductive structure 421 and the second conductive structure 422 may be formed with any suitable conductive material. For example, the first conductive structure 421 and the second conductive structure 422 may comprise copper or the like. The first conductive structure 421 and the second conductive structure 422 may be formed with a plating process, such as an electrolytic plating process, or the like.

Referring now to FIG. 4F, a cross-sectional illustration of the package substrate 400 after the mask layer 441 is removed is shown, in accordance with an embodiment. In an embodiment, the mask layer 441 may be removed with a resist stripping process, an etching process, or the like. Removal of the mask layer 441 results in the exposure of the seed layer 425 over the outer floating portions of the core 405. The exposed portions of the seed layer 425 are located at positions where the air gaps are desired.

Referring now to FIG. 4G, a cross-sectional illustration of the package substrate 400 after the exposed portions of the seed layer 425 are removed is shown, in accordance with an embodiment. In an embodiment, the exposed portions of the seed layer 425 may be removed with a flash etching process or the like. Removal of the seed layer 425 results in the exposure of portions of the underlying core 405.

Referring now to FIG. 4H, a cross-sectional illustration of the package substrate 400 after the floating portions of the core 405 are removed to form air gaps 410 is shown, in accordance with an embodiment. In an embodiment, the air gaps 410 may be formed by etching away the exposed portions of the core 405. For example, a wet etching process that is selective to the core 405 may be used to form the air gaps 410. In an embodiment, portions of the seed layer 425 along sidewalls of the air gaps 410 may also be removed. However, in some embodiments, portions of the seed layer 425 may persist on the sidewalls of the air gaps 410 in some embodiments. As shown, the air gaps 410 have tapered sidewalls.

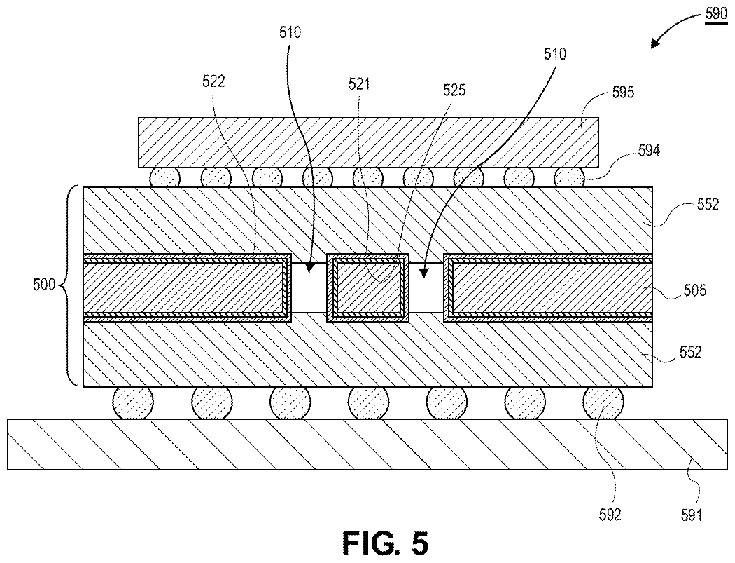

Referring now to FIG. 5, a plan view illustration of a multi-phase inductor structure

Referring now to FIG. 5, a cross-sectional illustration of an electronic system 590 is shown, in accordance with an embodiment. In an embodiment, the electronic system 590 may comprise a board 591, such as a printed circuit board (PCB) or the like. The board 591 may be coupled to a package substrate 500 by interconnects 592. The interconnects 592 may be solder bumps or any other interconnect architecture.

In an embodiment, the package substrate 500 may comprise a core 505, such as a glass core. In an embodiment, an air core inductor is provided in the core 505. The air core inductor comprises a first conductive structure 521 and a second conductive structure 522. The conductive structures 521 and 522 may be plated over seed layers 525. Additionally, air gaps 510 may be provided between the first conductive structure 521 and the second conductive structure 522. In an embodiment, the package substrate 500 may further comprise buildup layers 552 above and below the core 505. The buildup layers 552 may span across the air gaps 510. In some embodiments, the air gaps 510 remain free from any solid fill material.

In an embodiment, one or more dies 595 may be coupled to the package substrate 500. For example, interconnects 594 may be used to couple the die 595 to the package substrate 500. While shown as solder balls, it is to be appreciated that the interconnects 594 may include any first level interconnect (FLI) architecture. The die 595 may be a compute die, a graphics processor die, a memory die, or any other type of die.

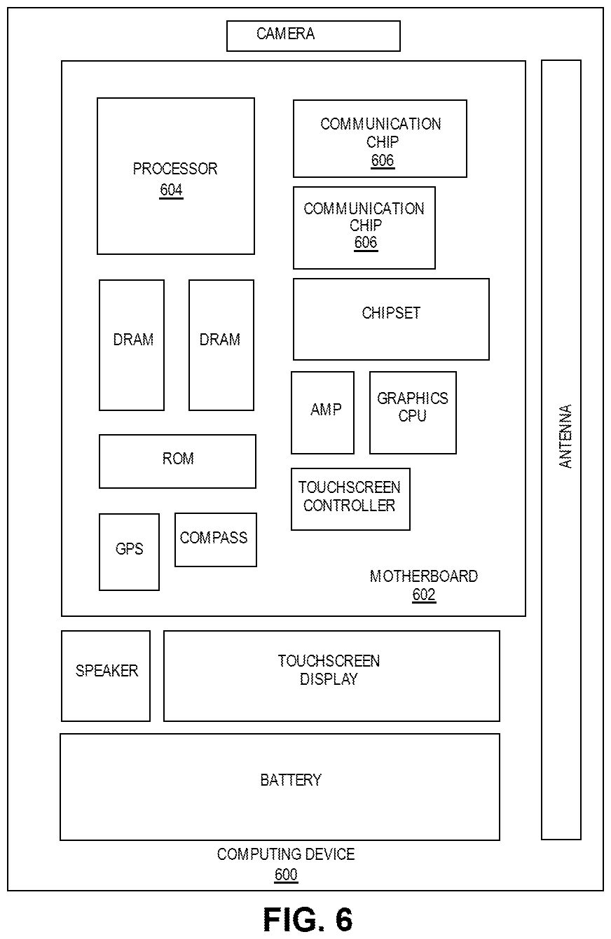

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor may be part of an electronic package that comprises a glass core with true air core inductors, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip may be part of an electronic package that comprises a glass core with true air core inductors, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package core, comprising: a core substrate; a first opening through the core substrate; a second opening through the core substrate and adjacent to the first opening; a first structure around the core substrate between the first opening and the second opening, wherein the first structure is electrically conductive; and a second structure around the core substrate outside of the first opening and the second opening, wherein the second structure is electrically conductive.

Example 2: the package core of Example 1, wherein a seed layer is provided between the core substrate and the first structure and between the core substrate and the second structure.

Example 3: the package core of Example 1 or Example 2, wherein the first structure and the second structure comprise an inductor.

Example 4: the package core of Examples 1-3, wherein an air gap is provided between the first structure and the second structure.

Example 5: the package core of Examples 1-4, wherein a sidewall of the first structure and a sidewall of the second structure are substantially vertical.

Example 6: the package core of Examples 1-4, wherein a sidewall of the first structure and a sidewall of the second structure are tapered.

Example 7: the package core of Example 6, wherein the sidewall of the first structure and the sidewall of the second structure are each tapered in a first direction and a second direction.

Example 8: the package core of Examples 1-7, wherein the core substrate

comprises glass.

Example 9: the package core of Examples 1-8, wherein a thickness of the core substrate is between approximately 50 μm and approximately 1,000 μm, and wherein aspect ratios (height:width) of the first opening and the second opening are approximately 5:1 or greater.

Example 10: the package core of Examples 1-9, wherein the package core is coupled to a processor of a computing system.

Example 11: a method of forming an air core inductor in a substrate, comprising: forming a first series of holes through the substrate; forming a seed layer along surfaces of the substrate; masking portions of the substrate between selected ones of the first series of holes with a mask; plating a first structure and a second structure over exposed portions of the seed layer, wherein the first structure and the second structure fill the first series of holes; removing the mask; and etching through the substrate to form a second series of holes between the first structure and the second structure.

Example 12: the method of Example 11, wherein the first series of holes comprises a first hole, a second hole, a third hole, and a fourth hole.

Example 13: the method of Example 12, wherein the mask is provided between the first hole and the second hole, and between the third hole and the fourth hole.

Example 14: method of Examples 11-13, wherein the first series of holes have substantially vertical sidewalls.

Example 15: the method of Examples 11-14, wherein the first series of holes have hourglasses shaped profiles.

Example 16: the method of Examples 11-15, wherein the substrate comprises

glass.

Example 17: the method of Examples 11-16, wherein the first series of holes are formed with a laser ablation process.

Example 18: the method of Examples 11-17, wherein the first series of holes are formed with a laser assisted patterning process.

Example 19: the method of Examples 11-18, wherein the first structure is separated from the second structure by an air gap.

Example 20: the method of Examples 11-19, wherein the seed layer is applied with a sputtering process.

Example 21: a package substrate, comprising: a core, wherein the core comprises glass; buildup layers above and below the core; and an air core inductor embedded in the core, wherein the air core inductor comprises a first conductive structure and a second conductive structure that are separated from each other by an air gap.

Example 22: the package substrate of Example 21, wherein the air core inductor comprises a plurality of conductive loops.

Example 23: the package substrate of Example 21 or Example 22, wherein the first conductive structure and the second conductive structure pass through a thickness of the core.

Example 24: an electronic system, comprising: a board; a package substrate coupled to the board, wherein the package substrate comprises: an air core inductor embedded in a core of the package substrate; and a die coupled to the package substrate.

Example 25: the electronic system of Example 24, wherein the air core inductor passes through a thickness of the core, and wherein sidewalls of the air core inductor are tapered.

What is claimed is:

1. A package core, comprising:
a core substrate;
a first opening through the core substrate;
a second opening through the core substrate and adjacent to the first opening;
a first structure around the core substrate between the first opening and the second opening, wherein the first structure is electrically conductive; and
a second structure around the core substrate outside of the first opening and the second opening, wherein the second structure is electrically conductive.

2. The package core of claim 1, wherein a seed layer is provided between the core substrate and the first structure and between the core substrate and the second structure.

3. The package core of claim 1, wherein the first structure and the second structure comprise an inductor.

4. The package core of claim 1, wherein an air gap is provided between the first structure and the second structure.

5. The package core of claim 1, wherein a sidewall of the first structure and a sidewall of the second structure are substantially vertical.

6. The package core of claim 1, wherein a sidewall of the first structure and a sidewall of the second structure are tapered.

7. The package core of claim 6, wherein the sidewall of the first structure and the sidewall of the second structure are each tapered in a first direction and a second direction.

8. The package core of claim 1, wherein the core substrate comprises glass.

9. The package core of claim 1, wherein a thickness of the core substrate is between approximately 50 μm and approximately 1,000 μm, and wherein aspect ratios (height:width) of the first opening and the second opening are approximately 5:1 or greater.

10. The package core of claim 1, wherein the package core is coupled to a processor of a computing system.

11. A method of forming an air core inductor in a substrate, comprising:
forming a first series of holes through the substrate;
forming a seed layer along surfaces of the substrate;
masking portions of the substrate between selected ones of the first series of holes with a mask;
plating a first structure and a second structure over exposed portions of the seed layer, wherein the first structure and the second structure fill the first series of holes;
removing the mask; and
etching through the substrate to form a second series of holes between the first structure and the second structure.

12. The method of claim 11, wherein the first series of holes comprises a first hole, a second hole, a third hole, and a fourth hole.

13. The method of claim 12, wherein the mask is provided between the first hole and the second hole, and between the third hole and the fourth hole.

14. The method of claim 11, wherein the first series of holes have substantially vertical sidewalls.

15. The method of claim 11, wherein the first series of holes have hourglasses shaped profiles.

16. The method of claim 11, wherein the substrate comprises glass.

17. The method of claim 11, wherein the first series of holes are formed with a laser ablation process.

18. The method of claim 11, wherein the first series of holes are formed with a laser assisted patterning process.

19. The method of claim 11, wherein the first structure is separated from the second structure by an air gap.

20. The method of claim 11, wherein the seed layer is applied with a sputtering process.

21. A package substrate, comprising:
a core, wherein the core comprises glass;
buildup layers above and below the core; and
an air core inductor embedded in the core, wherein the air core inductor comprises a first conductive structure and a second conductive structure that are separated from each other by an air gap.

22. The package substrate of claim 21, wherein the air core inductor comprises a plurality of conductive loops.

23. The package substrate of claim 21, wherein the first conductive structure and the second conductive structure pass through a thickness of the core.

24. An electronic system, comprising:
a board;
a package substrate coupled to the board, wherein the package substrate comprises:
an air core inductor embedded in a core of the package substrate; and
a die coupled to the package substrate.

25. The electronic system of claim 24, wherein the air core inductor passes through a thickness of the core, and wherein sidewalls of the air core inductor are tapered.
